(19) United States
(12) Patent Application Publication
(10) Pub. No.: US 2010/0078630 A1
(43) Pub. Date: Apr. 1, 2010

(54) Organic Electroluminescence Element, Method for Manufacturing the Same, Image Display Unit and Illuminating Device

(75) Inventors: Shingo Kaneta, Tokyo (JP); Ryo Shoda, Tokyo (JP); Eiichi Kitazume, Tokyo (JP)

Correspondence Address: SQUIRE, SANDERS & DEMPSEY L.L.P., 1 MARITIME PLAZA, SUITE 300, SAN FRANCISCO, CA, 94111, US

(73) Assignee: Toppan Printing Co.,Ltd., Tokyo (JP)

(21) Appl. No.: 12/562,985

(22) Filed: Sep. 18, 2009

(30) Foreign Application Priority Data
Sep. 26, 2008 (JP) 2008-247813

(51) Int. Cl. H01L 51/52; H01L 51/56

(52) U.S. Cl. 257/40; 438/29; 257/E51.022

(57) ABSTRACT

In an organic electroluminescent element of the present invention, which has at least a hole transport layer having an inorganic compound and an organic luminescent layer between a first electrode and a second electrode on a substrate, a high light extraction efficiency can be obtained by reflecting light emitted from the organic luminescent layer off the hole transport layer.

### CROSS REFERENCE TO RELATED APPLICATION

This application is based on and claims the benefit of priority from the Japanese Patent Application number 2008-247813, filed on Sep. 26, 2008; the entire contents of which are incorporated herein by reference.

### BACKGROUND OF THE INVENTION

1. Field of the Invention

The present invention relates to a self-luminous organic electroluminescence element which is used for a display unit and an illuminating device.

2. Description of the Related Art

An organic electroluminescence element (heretofore referred to as an organic EL element) has a hole transport layer having a hole transport material, a luminescent layer having an organic luminous material or the like between two electrodes facing each other. By applying electrical current to the organic electroluminescence element, display light emitted from the organic luminescent layer is extracted from a light transmissive electrode. Although the organic electroluminescence element has a simple structure, it has got a lot of attention as a luminescence element which is capable of high intensity luminescence by driving a low voltage direct current. However, in the organic EL element, luminescence light being over a critical angle which is determined by a difference in a refractive index of the interfacial surface of the electrodes facing each other, the organic luminescent layer, a substrate or the like is all reflected and kept inside. Then, luminescence light which is over the critical angle disappears as a guided wave light. Moreover, there is a problem in that light extraction efficiency from the organic luminescent layer to the outside is poor and characteristics of the element are decreased because of a reduction in a luminescence pixel area caused by a TFT.

In order to eliminate the decrease in the light extraction efficiency, an organic EL element of a top emission structure is proposed for preventing a reduction in a luminescence pixel area caused by a TFT (refer to Patent Document 1). In a display device having a structure in which a method for improving the light extraction efficiency is utilized by having the top emission structure, it is possible to avoid a reduction in a luminescence pixel area caused by a TFT. However, there is a loss in light which is emitted in a back side direction. In patent document 1, a reflective layer is formed on a back side electrode or a reflective material is used for an electrode in order to improve light extraction efficiency.

However, it is difficult to efficiently extract luminescence light which disappears in an organic thin film. In other words, the above stated method can not eliminate the disappearance of luminescence light caused by scattering in an organic thin film and absorption into a partition wall which sections a luminescent layer.

Thus, the present invention provides an organic electroluminescence element which is capable of improving characteristics of the element and luminescence light extraction efficiency from an organic luminescent layer to the outside.

### Patent Document 1: JP-A 2006-100137

### SUMMARY OF THE INVENTION

One embodiment of the present invention is an organic electroluminescence element having at least a hole transport layer which has an inorganic compound and an organic luminescent layer between a first electrode and a second electrode on a substrate while light emitted from the organic luminescent layer is reflected off the hole transport layer.

### BRIEF DESCRIPTION OF THE DRAWINGS

FIG. 1 is a schematic cross sectional diagram of an organic electroluminescence display unit in one embodiment of the present invention.

FIG. 2 is a schematic cross sectional diagram of a stacked layer portion of an organic electroluminescence element in one embodiment of the present invention.

FIG. 3 is a schematic cross sectional diagram of an organic electroluminescence display unit in one embodiment of the present invention.

FIG. 4 is a schematic cross sectional diagram of an organic electroluminescence display unit in one embodiment of the present invention.

FIG. 5 is a schematic cross sectional diagram of an organic electroluminescence display unit in one embodiment of the present invention.

FIG. 6 is a schematic cross sectional diagram of a relief printing apparatus in one embodiment of the present invention.

100:an organic electroluminescence display unit, 101:a substrate, 102a:a first electrode (an anode), 102b:a first electrode (a cathode), 103:a partition wall, 104:a hole transport layer, 105:an interlayer, 106:an organic luminescent layer, 107a:a second electrode (a cathode), 107b:a second electrode (an anode), 108:a sealing body, 109:a sealing material, 110:a resin layer, 112:a luminescent medium layer, 300:a relief printing apparatus, 301:a stage, 302:a substrate to be printed, 303:an ink tank, 304:an ink chamber, 305:an anilox roll, 306:a doctor, 307:a relief plate, 308:a plate cylinder, 309:an ink layer

### DETAILED DESCRIPTION OF THE INVENTION

The embodiments of the present invention are explained below using the figures. The figures referred to in the following explanations of the embodiments are for the explanations of the structures of the present invention. Therefore, ratios of an illustrated size, thickness, length or the like do not show the actual embodiments of the present invention.

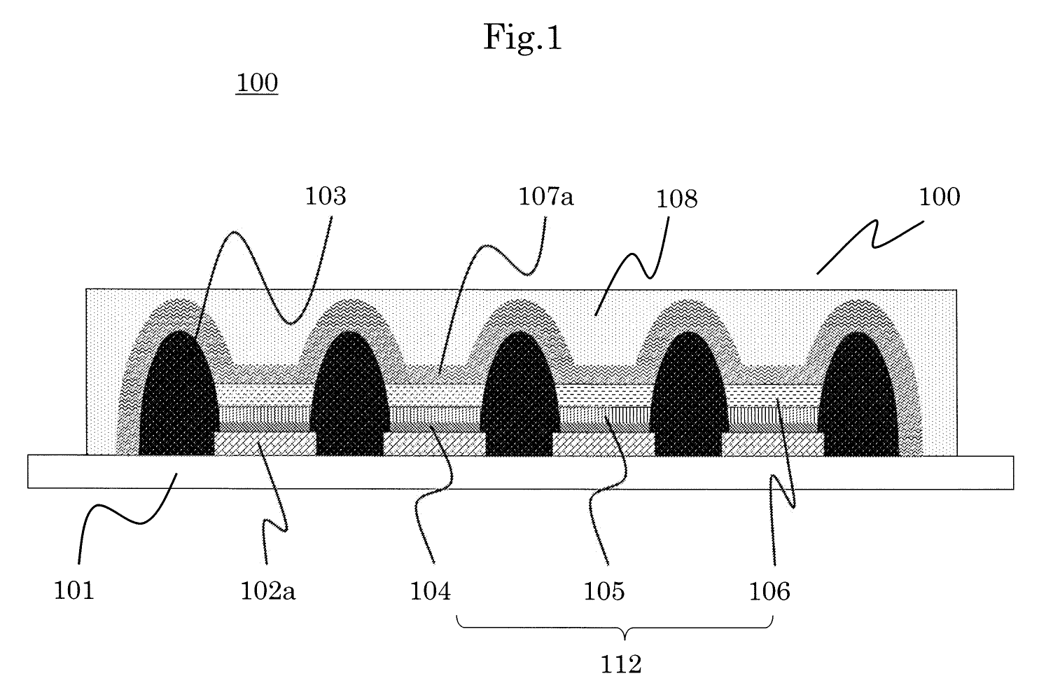

FIG. 1 is a schematic cross sectional diagram of an organic electroluminescence display unit in one embodiment of the present invention. A display unit 100 which utilizes an organic electroluminescence display element of one embodiment of the present invention shown in FIG. 1 has on a substrate 101 a first electrode (an anode) 102a formed in respective pixels, a partition wall 103 which sections pixels of the first electrode, a hole transport layer 104 formed on the first electrode, an interlayer 105 formed on the hole transport layer, an organic luminescent layer 106 formed on the interlayer, a second electrode (a cathode) 107a formed on the organic luminescent layer so as to cover the entire surface of the organic luminescent layer and the partition wall, a luminescent medium layer which includes the first electrode, the partition wall, the hole transport layer, the interlayer and the organic luminescent layer and a sealing body 108 which has contact with the substrate 101 so as to cover the second electrode.

Here, the luminescent medium layer 112 is sandwiched between the first electrode (an anode) 102a and the second electrode (a cathode) 107a. In the element shown in FIG. 1, the hole transport layer 104, the interlayer 105 and the organic luminescent layer 106 are the luminescent medium layer. A hole injection layer, an electron transport layer, an electron injection layer or the like can be formed arbitrarily other than the above layers.

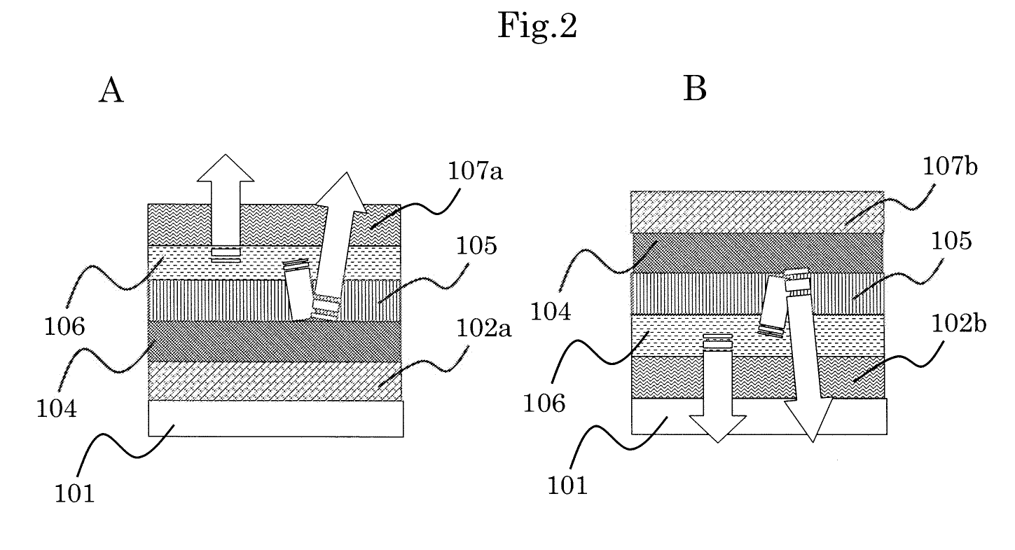

FIGS. 2A and 2B are cross sectional diagrams of a stacked layer portion of an organic electroluminescence element of the present invention. FIG. 2A is an example of an organic electroluminescence element of a top emission type where a first electrode (an anode) 102a, a hole transport layer 104, an organic luminescent layer 106 and a second electrode (a cathode) 107a are stacked on a substrate 101 in this order. An interlayer 105 or other layers can be stacked between the above respective layers as long as the above layers are stacked in this order. The second electrode is a transparent electrode. Light emitted in the second electrode direction comes outside through the second electrode. On the other hand, light emitted in the first electrode direction is reflected on the hole transport layer and comes outside through the second electrodes as well as the light emitted in the second electrode direction. Therefore, efficiency of extracting luminescence light to the outside can be improved due to light reflected on the hole transport layer.

FIG. 2B is an example of an organic electroluminescence element of an opposite structure type which has a first electrode (a cathode) 102b, an organic luminescent layer 106, a hole transport layer 104 and a second electrode (an anode) 107b stacked on a substrate 101 in this order. An interlayer 105 or other layers can be stacked between the above respective layers as long as the above layers are stacked in the described order. The substrate 101 and the first electrode are transparent electrodes. Light emitted in the first electrode direction comes outside transmitted through the first electrode and the substrate. On the other hand, light emitted in the second electrode direction is reflected on the hole transport layer and comes outside through the first electrode the same as the above. Therefore, an efficiency of extracting light to the outside can be improved due to the light reflected on the hole transport layer the same as the case of the top emission type. The following explanation is about an organic electroluminescence element of a top emission type. However, an opposite structure type in which a cathode and an anode are replaced mutually and the order of forming a luminescent medium layer is the opposite of that of the top emission type can also be applicable.

The hole transport layer 104 in an organic electroluminescence element of the present invention has a property of reflecting light emitted from an organic luminescent layer as is clear from the above principle. In particular, an average reflectance ratio of the hole transport layer for luminescence light wavelength from a luminescent layer is preferred to be equal to or more than 50%, more preferably equal to or more than 70%. Therefore, in an organic electroluminescence element used for an organic electroluminescence display unit of full colored luminescence, a reflectance ratio for respective luminescence lights of visible light areas is required to be equal to or more than 50%. Therefore, a hole transport layer material having a reflectance ratio of equal to or more than 50% in the visible light areas is preferable. In an organic element used for an illuminating device of white color light, the hole transport layer having the same properties can be preferably used.

On the other hand, in an organic electroluminescence element of a single color luminescence, only wavelength of emitted light is required to be reflected. Therefore, it is sufficient when a reflectance ratio for a particular wavelength is high. Moreover, although the steps for manufacturing an organic luminescence display unit increase, a material having a high reflectance ratio for a particular wavelength can also be used in the organic electroluminescence display unit having a full color luminescence, while a hole transport layer is patterned and the hole transport layers having film formation materials which differ depending on pixels of respective luminescence colors are formed.

As a physical property of the hole transport layer, a work function of the hole transport layer is preferred to be equal to or more than that of the anode (102a and 102b) such that a hole can be injected into an interlayer or a luminescent layer from the anode efficiently. Although a work function differs depending on a material for an anode and for an upper layer, the hole transport layer having a work function of 4.5 eV-6.5 eV can be used. When the anode is ITO or IZO, particularly the hole transport layer having the work function of 5.0 eV-6.0 eV can be used preferably. Although resistivity of the hole transport layer differs depending on a patterning method, the resistivity is preferred to be 1×10³˜5×10⁸ Ω·m, more preferably 5×10⁴˜1×10⁷ Ω·m in order to prevent the hole from leaking. In addition, the thickness of the hole transport layer differs depending on a material property. However, the thickness is preferred to be equal to or less than 100 nm considering the above mentioned resistivity. On the other hand, when the thickness of the hole transport layer is thin, light can be transmitted through the hole transport layer and extraction efficiency is decreased. Therefore, the thickness is preferred to be equal to or more than 10 nm.

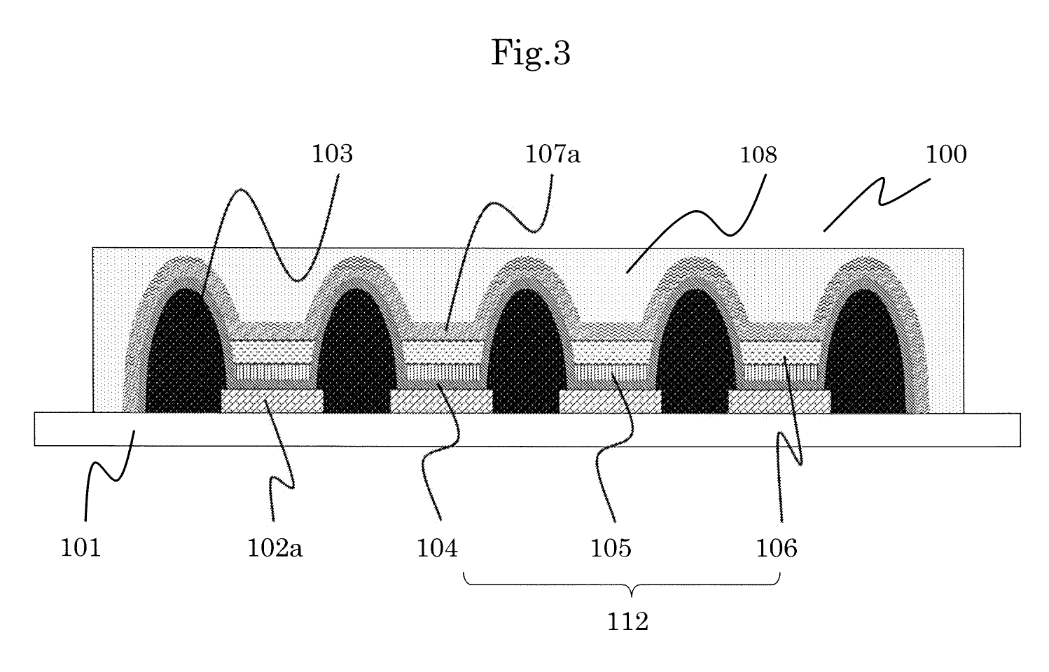

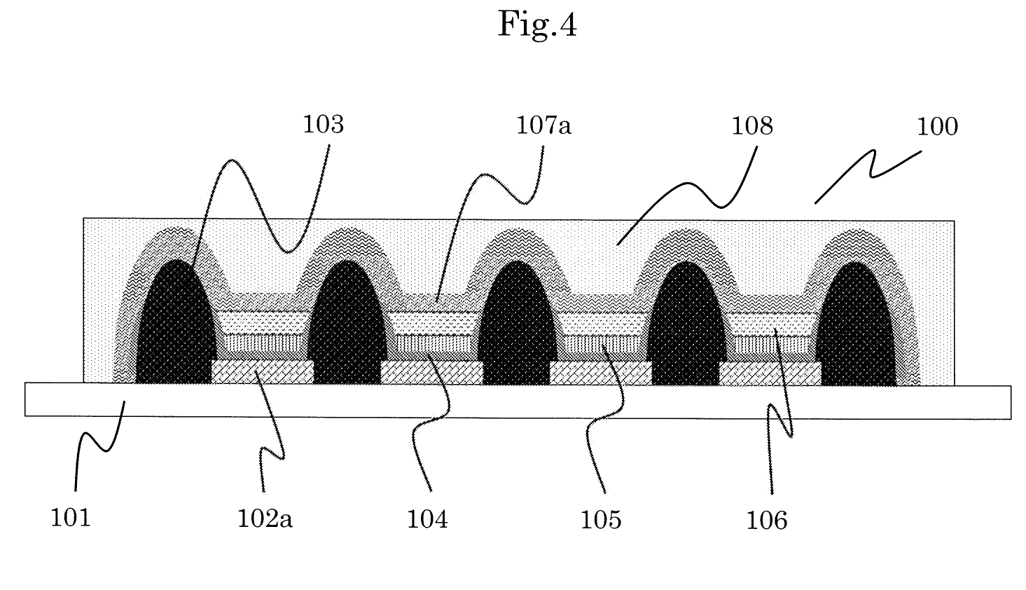

As shown in FIG. 3, when a hole transport layer 104 is formed on a substrate on which a partition wall is formed in an organic electroluminescence element display unit of a top emission type, the hole transport layer is also formed on the partition wall preferably. By covering the partition wall by the hole transport layer, luminescence light which is scattered and absorbed by a partition wall or guided in the luminescent medium layer can be reflected and extraction efficiency to the outside can be improved. In addition, all that's required is that the formed transport layer is formed on the entire surface of a display area including the partition wall. Therefore, the hole transport layer can be easily formed because patterning and position adjustment for respective pixels are not required. Moreover, as shown in FIG. 4, the hole transport layer can be patterned so as not to be formed on the partition wall 103. Light which is guided in the luminescent medium layer or scattered can be reflected, because the proximity of the luminescent medium layer formed on the hole transport layer is covered by the hole transport layer, even though the partition wall is not entirely covered by the hole transport layer.

As a material for the substrate 101, for example, glass or quartz, or a plastic film or sheet such as polypropylene, polyethersulfone, polycarbonate, cyclo olefin polymer, polyarylate, polyamide, polymethylmethacrylate, polyethylene terephthalate and polyethylene naphthalate can be used. Alternatively, in the case of an organic electroluminescence element of a top emission type, in addition to the above, a translucent base material where a film of metallic oxide such as silicium oxide or aluminum oxide, metal fluoride such as aluminum fluoride or magnesium fluoride, metal nitrides such as silicon nitride or aluminum nitride, metal oxynitride such as silicon oxide nitride and high molecular resin films such as acryl resin, epoxy resin, silicone resin or polyester resin formed on a plastic film and sheet can be used. Furthermore, a translucent base material where a plurality of layers of the above are stacked can be used. In addition, as a non-translucent base material, a metal foil, sheet or plate which are made of aluminum, stainless or the like or a layer where a metal film such as aluminum, copper, nickel or stainless is stacked on the plastic film or sheet can be used. However, a usable material is not limited to these in the present invention.

A surface where light is extracted can be an electrode side which faces the substrate 101 in the organic electroluminescence display unit 100. The substrate 101 having the above mentioned material on which exclusion of moisture or hydrophobic treatment has been preferably performed is used in order to avoid entry of moisture to the organic electroluminescence display unit 100. Exclusion of moisture and hydrophobic treatment can be performed by forming an inorganic film, applying a resin or the like to one surface or the entire surface of the substrate 101. In particular, moisture content and a gas permeation factor of the substrate 101 may be preferably low in order to avoid entry of moisture to a luminescent medium layer 112.

The film of a first electrode 102 in an embodiment of the present invention is formed on the substrate 101 and patterned as necessary. When a luminescent layer is formed by a coating type organic luminous material, in an organic luminescence element used for an organic electroluminescence display unit of a full color luminescence, the first electrode 102 is sectioned by a partition wall 103. Thus, the first electrode becomes a pixel electrode which corresponds to each pixel.

As a material for the first electrode 102, a metal compound oxide such as ITO (indium tin compound oxide), indium zinc compound oxide, zinc aluminum compound oxide, a metal material such as gold and platinum, and a monolayer or multilayer of a particle dispersion membrane which is made by dispersing particles of the metal compound oxide and the metal material into epoxy resin, acrylic resin or the like can be used. However, a material is not limited to these in the present invention.

When the first electrode 102 is an anode, a material having a high work function such as ITO is preferably selected as the first electrode. In addition, when the first electrode is a cathode in the opposite structure, a material having a low work function such as Ag is preferably selected as the first electrode. In an organic electroluminescence display unit which is driven with a TFT, an electrode may have a low value resistance. Furthermore, the electrode is preferably used when a sheet resistance of the electrode is equal to or less than 20Ω/□.

As a method for forming the first electrode 102, an existing film formation method, for example, a dry film formation method such as a vapor deposition method, an electron beam deposition method, a reactive deposition method, an ion plating method and a sputtering method or a wet film formation method such as an ink jet printing method, a gravure printing method and a screen printing method can be used depending on a material used for the first electrode. However, a method is not limited to these in the present invention.

As a method for pattering the first electrode 102, an existing patterning method such as a mask deposition method, a photolithographic method, a wet etching method and a dry etching method can be used depending on a material and a film formation method.

The partition wall 103 in one embodiment of the present invention can be formed so as to section a luminescent area which corresponds to each pixel. The partition wall is preferably formed so as to cover the edge part of the first electrode 102 (refer to FIG. 1). Generally in an organic electroluminescence display unit of an active matrix drive type 100, the first electrode 102 is formed corresponding to respective pixels so that respective pixels posses an area as large as possible. Therefore, the partition wall is formed so as to cover the edge part of the first electrode 102. The most preferable shape of the partition wall 103 is based on a grid shape which can section the pixel electrode 102 in the shortest way.

A material for the partition wall 103 is required to have an insulating property and a photosensitive material or the like can be used. A photosensitive material can be either a positive type or a negative type. Moreover, a radical photopolymerization or a cationic photopolymerization light curing resin, a copolymer which includes an acrylonitrile component, polyvinyl phenol, polyvinyl alcohol, novolak resin, polyimid resin, cyanoethyl pullulan or the like can be used as a photosensitive material. In addition, as a material for forming a partition wall, SiO₂, TiO₂ or the like can be used.

A height of the partition wall 103 is preferably equal to or more than 0.1 μm and equal to or less than 10 μm, more preferably is about 0.5-2 μm. When the height is more than 10 μm, the height interrupts a formation of a counter electrode 107 and sealing. When the height is less than 0.1 μm, the partition wall can not entirely cover the edge part of the pixel electrode 102 or a short circuit and a mixed color with an adjacent pixel can be caused at the time of forming the luminescent medium layer 112.

As a method for forming the partition wall 103, an existing film formation method, for example, a dry film formation method such as a vapor deposition method, an electron beam deposition method, a reactive deposition method, an ion plating method and a sputtering method or a wet film formation method such as an ink jet printing method, a gravure printing method and a screen printing method can be used depending on a material used for the partition wall. However, a method is not limited to these in the present invention.

As a method for patterning the partition wall 103, a method in which dry etching is performed after forming an inorganic film uniformly on a base body (a base material 101 and the first electrode 102) and performing masking with a resist or a method in which photosensitive resin is applied to the base body, and the resin is patterned to be a predetermined shape by a photolithographic method can be used. However, a method is not limited to these in the present invention. If necessary, a water repellent agent can be added to the resist and the photosensitive resin or the partition wall may have a multilayer structure of a hydrophilic material and a hydrophobic material. In addition, the partition wall can have a water-repellent property or a hydrophilic property to an ink by irradiating plasma or UV after forming the partition wall 103.

In the case of an organic electroluminescence element of a top emission type, the hole transport layer 104 is formed on the first electrode. As a method for forming the hole transport layer, an existing film formation method, for example, a dry film formation method such as a vapor deposition method, an electron beam deposition method, a reactive deposition method, an ion plating method and a sputtering method or a wet film formation method such as a spin coating method and a sol-gel method can be used. However, a method is not limited to these in the present invention and a general film formation method can be utilized. In particular, when a dry film formation method is utilized, the hole transport layer with an excellent flatness and uniformity can be formed. In addition, an inorganic film of a mixed composition can be formed by forming a film of a hole transport material which is a main component and an inorganic material which can cause metallic brilliance at the same time as mentioned later. Therefore, the hole transport layer with a high reflectance ratio can be formed while maintaining the properties of the hole transport layer.

As a material for the hole transport layer 104 (a hole transport material), a single layer or a stacked structure of multilayers of an inorganic compound which includes at least one kind of transition metal oxide such as Cu₂O, Cr₂O₃, Mn₂O₃, NiO, CoO, Pr₂O₃, Ag₂O, MoO₂, ZnO, TiO₂, V₂O₅, Nb₂O₅, Ta₂O₅, MoO₃, WO₃, MnO₂, or nitride or sulfide of the same transition metal oxide can be utilized.

A method for patterning the hole transport layer 104 differs depending on a material property and a film formation method. However, a solid film formation by which the hole transport layer is formed so as to cover the first electrode 102 and the partition wall 103 is easily performed. In addition, as mentioned with respect to FIG. 4, patterning can be performed so as not to form the hole transport layer 104 on the partition wall 103 by a mask deposition method. Light scattered or guided through the luminescent medium layer can be reflected by covering the proximity of the luminescent medium layer even though the entire surface of the partition wall is not covered.

The work function and resistivity of the hole transport layer can be optimized by controlling a nitride proportion, sulfurization proportion or oxidation proportion. The method for controlling a nitride proportion, sulfurization proportion or oxidation proportion differs depending on each film formation method. When a vapor deposition method or a sputtering method is used, the control can be performed by arranging an ion source having reactive ions which are required in a chamber or purging vapor having required reactive molecules during the film formation. Alternatively, the control of a nitride proportion, sulfurization proportion or oxidation proportion of the hole transport layer can be performed by a heating treatment under a required gaseous atmosphere after the film formation. In addition, in the case of the hole transport layer having a mixture of a plurality of inorganic compounds, the nitride proportion, sulfurization proportion or oxidation proportion can be controlled depending on the mixture proportion.

A hole transport layer which has a high reflectance ratio can be formed by including a material which produces metal brilliance in the hole transport layer. Or, it can be formed by including a material which causes metal brilliance in the hole transport layer while controlling a nitride proportion, sulfurization proportion or oxidation proportion in a film formation process. Alternatively, it can be formed by including a material which has metal binding by mixing with a hole transport material (an inorganic material) which is a main component in the hole transport layer. For example, although indium oxide (In₂O₃) which is used in the example is not a material which produces metal brilliance, a hole transport layer which is film-formed by mixing and depositing indium oxide and molybdenum oxide which is a main component together has a reflectance ratio equal to or more than 50%. One of the reasons why the hole transport layer has this kind of reflectance ratio property is because oxygen is removed from indium oxide in a film formation stage and metal brilliance can be produced.

More logically, when metal oxide is included in the hole transport layer, metal brilliance is produced because the wavelength of plasma vibration frequency is higher than the luminescence wavelength of the element while plasma vibration is caused by free holes which exists in the valence band with oxygen loss. Therefore, a material mixed with the hole transport layer is preferred to be metal oxide where oxygen is removed at the time of film formation. In addition, a single film of a material having a work function of 4.0-6.5 eV is preferably used in order not to influence the work function of the film formed after mixing with the hole transport layer. As an inorganic material which is added to the hole transport layer in order to produce metal brilliance, indium oxide, vanadium oxide, titanic oxide (TiO₂), zinc oxide (ZnO), nickel oxide (NiO), tungsten oxide (Ta₂O₅), molybdenum oxide (MoO₂), silver oxide (Ag₂O), cobalt oxide (CoO), chrome oxide (Cr₂O₃), ruthenium oxide (RuO₂), iridium oxide (In₂O₃) or the like can be used. The same material can be used for the hole transport material and the above mentioned metal oxide material which is added to the hole transport layer. In addition, the metal oxide material can increase the amount of oxygen loss of the hole transport layer material. However, for example, when the film of the hole transport layer is formed by mixing and depositing a hole transport material and a metal oxide material together and the metal material is different from the hole transport material, oxygen loss can be increased only in the added metal oxide material because of difference in easiness in oxygen loss at the time of deposition and difference in a reactive property for an argon ion beam. Therefore, the characteristics and the reflectance ratio of the hole transport layer can be easily compatible.

The film of the hole transport layer is formed such that oxygen is removed from these stable oxides, in other words, the hole transport layer is formed so that an amount of oxygen loss is equal to or more than 10%. Here, in the case where an added inorganic material is stable, the ratio of oxygen atoms to metal atoms is called “0%”. The less the amount of oxygen atoms become, the more the amount of oxygen loss. For example, the stable state of molybdenum oxide (MoO₂) is Mo/O(2)=0.50 and the oxygen loss δ is 0%. On the condition that the proportion of oxygen atoms to one molybdenum oxide atom is 1.5, molybdenum oxide becomes Mo/O(1.5)=0.66 and the oxygen loss δ=the proportion of the oxygen loss/the proportion of oxygen atoms having no oxygen loss=(2−1.5)/2 and 25%. In addition, as long as the metal valance is not transited, in other words, as long as the structure of metal oxide does not change, the amount of oxygen loss is not limited.

A film which includes this kind of oxygen loss can be formed with oxygen loss by depositing a material from which oxygen can be easily removed. Alternatively, oxygen loss can be increased by irradiating the formed film, for example, with an argon ion beam or the like.

This kind of amount of oxygen loss can be estimated by performing an elemental analysis of a solid surface, using X-ray photoelectron spectroscopy (XPS), Electron Spectroscopy for Chemical Analysis (ESCA), Auger electron spectroscopy (AES) or X-ray Excited Auger Electron Spectroscopy (XAES).

An added amount of inorganic compound is not limited particularly as long as it does not harm the function of the hole transport layer. However, the relative proportion of the added inorganic compound to all the materials used for the hole transport layer is preferably equal to or less than 70%. That is because it is possible that the property of the hole transport layer is not maintained if too much of the inorganic compound is added since the added inorganic compound has a substantially lower value resistance and a lower work function than a main component.

The luminescence life time of the element can be improved by stacking an interlayer 105 in one embodiment of the present invention between an organic luminescent layer and a hole transport layer. In the element structure of a top emission type, the interlayer can be stacked after the hole transport layer 104 is formed. Generally, the interlayer is formed so as to cover the hole transport layer 104. However, the interlayer can be patterned as necessary.

As a material for the interlayer 105, an organic material such as polyvinyl carbazole, polyvinylcarbazole derivative or polymers having aromatic amine such as polyarylene derivative, aryl amine derivative and triphenyl diamine derivative can be used. The above mentioned three derivatives have aromatic amine in a main chain or a side chain. In addition, an inorganic material which includes at least one kind of transition metal oxide such as Cu₂O, Cr₂O₃, Mn₂O₃, NiO, CoO, Pr₂O₃, Ag₂O, MoO₂, ZnO, TiO₂, V₂O₅, Nb₂O₅, Ta₂O₅, MoO₃, WO₃, MnO₂ or nitride or sulfide of the same transition metal can be used. However, a usable material is not limited to these materials in the present invention.

An organic interlayer ink can be produced by dissolving or stably dispersing one of the organic materials in a solvent. As the solvent in which the organic interlayer material is dissolved or dispersed, toluene, xylene, acetone, anisole, methyl ethyl ketone, methyl isobutyl ketone, cyclohexanone can be used. The above-mentioned solvent may be used either as a single solvent or as a mixed solvent. Above all, an aromatic organic solvent such as toluene, xylene and anisole is preferably used due to an aspect of solubility of the organic interlayer material. In addition, a surface active agent, an antioxidant, a viscosity modifier or an ultraviolet absorber may be added to the organic interlayer ink if necessary

As a material for the interlayer, a material with a work function equal to or more than that of the hole transport layer 104 is preferably selected. Moreover, using a material with the work function equal to or less than that of the organic luminescent layer 105 is preferable. Thus, when carriers are injected from the hole transport layer 104 into the organic luminescent layer 105, an unnecessary injection barrier is not formed. In addition, a band gap of the interlayer is preferably equal to or more than 3.0 eV, more preferably equal to or more than 3.5 eV in order to obtain an effect of confining an electric charge which could not contribute to luminescence from the organic luminescent layer 105.

As a method for forming the interlayer 105, an existing film formation method, for example, a dry film formation method such as a vapor deposition method, an electron beam deposition method, a reactive deposition method, an ion plating method and a sputtering method or a wet film formation method such as an ink jet printing method, a relief printing method, a gravure printing method and a screen printing method can be used depending on a material used for the interlayer. However, a method is not limited to these in the present invention.

In the case of the element of a top emission type, the organic luminescent layer 106 in one embodiment of the present invention can be stacked after forming the interlayer 105. When the display light emitted form the organic luminescent layer 106 is a single color, the organic luminescent layer 106 is formed so as to cover the interlayer 105. In addition, the organic luminescent layer 106 can be patterned and preferably used if necessary in order to obtain a display light of multiple colors.

As an organic luminous material forming the organic luminescent layer 106, the materials which are made by scattering a luminous pigment in high molecule can be used. Coumarin system, perylene system, pyran system, anthrone system, porufiren system, quinacridon system, N,N′-dialkyl permutation quinacridon system, naphthalimido system, N,N′-diaryl permutation pyrrolo pyrrole series and iridium complex system are examples of the luminous pigments, and polystyrene, polymethyl methacrylate and polyvinyl carbazole are examples of the high molecules. Alternatively, high molecular materials such as poly arylene system, polyarylenevinylene system or a poly fluorene system can be used for the organic luminescent materials. However, a material is not limited to these materials in the present invention.

These organic luminous materials can be an organic luminous ink by dissolving or stably dispersing in a solvent. As the solvent in which the organic luminous material is dissolved or dispersed, toluene, xylene, acetone, anisole, methyl ethyl ketone, methyl isobutyl ketone, cyclohexanone can be used. The above-mentioned solvent may be used either as a single solvent or as a mixed solvent. Above all, an aromatic organic solvent such as toluene, xylene and anisole is used preferably due to an aspect of solubility of the organic luminous material. In addition, a surface active agent, an antioxidant, a viscosity modifier or an ultraviolet absorber may be added to the organic luminous ink if necessary

In addition to the above mentioned high molecular materials, a low molecular luminous material can be used. For example, 9,10-diaryl anthracenes complex, pyrene, coronene, perylene, rubrene, 1,1,4,4-tetraphenylbutadiene, tris(8-hydroxyquinolonate)aluminum complex, tris(4-methyl-8-hydroxyquinolonate)aluminum complex, bis(8-hydroxyquinolonate)zinc complex, tris(4-methyl-5-trifluoromethyl-8-hydroxyquinolonate)aluminum complex, tris(4-methyl-5-cyano-8-hydroxyquinolonate)aluminum complex, bis(2-methyl-5-trifluoromethyl-8-quinolinolate) [4-(4-cyanophenyl)phenolate]aluminum complex, bis(2-methyl-5-cyano-8-quinolinolate)[4-(4-cyanophenyl)phenolate]aluminum complex, tris(8-quinolinolate)scandium complex, bis[8-(para-tosyl)aminoquinoline]zinc complex and cadmium complex, 1,2,3,4-tetraphenylcyclopentadiene, poly-2,5-diheptyloxi-para-phenylenevinylene can be used.

As a method for forming the organic luminescent layer 106, an existing film formation method, for example, a dry film formation method such as a vapor deposition method, an electron beam deposition method, a reactive deposition method, an ion plating method and a sputtering method or a wet film formation method such as an ink jet printing method, a relief printing method, a gravure printing method and a screen printing method can be used depending on a material used for the organic luminescent layer 106. However, a method is not limited to these in the present invention.

Next, a second electrode 107 in one embodiment of the present invention is formed on the organic luminescent layer. As a particular material for the second electrode 107, a metal simple substance such as Mg, Al, Yb or the like can be used. Moreover, a stacked film including the film of Al or Cu which has a high stability and electric conductivity and about 1 nm of a film made of an alloy of Li, lithium oxide and LiF which is sandwiched between the film of Al or Cu and an interfacial surface of a luminescent medium layer 112 can be used. Alternatively, in order to create a balance between electron injecting efficiency and stability, an alloy of one or more of metals such as Li, Mg, Ca, Sr, La, Ce, Er, Eu, Sc, Y and Yb which have a low work function and metal elements such as Ag, Al, Cu or the like which are stable can be used. In particular, an alloy of MgAg, AlLi, CuLi or the like can be used. In addition, a transparent conductive film such as a metal composite oxide such as ITO (indium tin oxide), IZO (indium zinc oxide) or zinc aluminum composite oxide can be used.

The counter electrodes 107 in the top emission structure are required to have transparency to a visible light area because display light emitted from the luminescent medium layer 112 is transmitted through the counter electrode 107. The thickness of the counter electrode 107 is preferably equal to or less than 10 nm, more preferably 2-7 nm, when the material is a metal simple substance such as Mg, Al, Yb or the like. The thickness of the transparent conductive film is controlled and preferably used so that an average transmission of visible wavelength can be kept being equal to or more than 85%.

As a method for forming the second electrode 107, an existing film formation method, for example, a dry film formation method such as a vapor deposition method, an electron beam deposition method, a reactive deposition method, an ion plating method and a sputtering method or a wet film formation method such as an ink jet printing method, a gravure printing method and a screen printing method can be used depending on a material used for the second electrode 107. However, a method is not limited to these in the present invention.

Sealing is performed by adhering a sealing body 108 and the substrate 101 and surrounding the substrate 101 on which, for example, the first electrode 102, the partition wall 103, the luminescent medium layer 112 and the second electrode 107 are formed. At this time, the sealing body 108 is required to be transparent to a visible area, because display light is extracted from the luminescent medium layer through the sealing body 108 which is located on the opposite side of the substrate 101 in the top emission structure. As transparent properties, the average transmission of visible wavelength is preferably equal to or more than 85%.

Sealing can be performed as follows. First, for example, the first electrode 102, the partition wall 103, the luminescent medium layer 109 and the second electrode 107 are formed on the substrate 101. Then, a glass cap or a metal cap having a concave portion as a sealing body 108 is formed so that the first electrode, the organic luminescent medium layer and the second electrode are covered by the concave portion. Next, sealing is performed by adhering the cap and the surrounding of the layer and electrodes by an adhesive. Degradation in an element caused by moisture, gas or the like can be prevented by performing sealing under an inert gas atmosphere such as nitrogen gas where a moisture absorbent is formed on the concave portion.

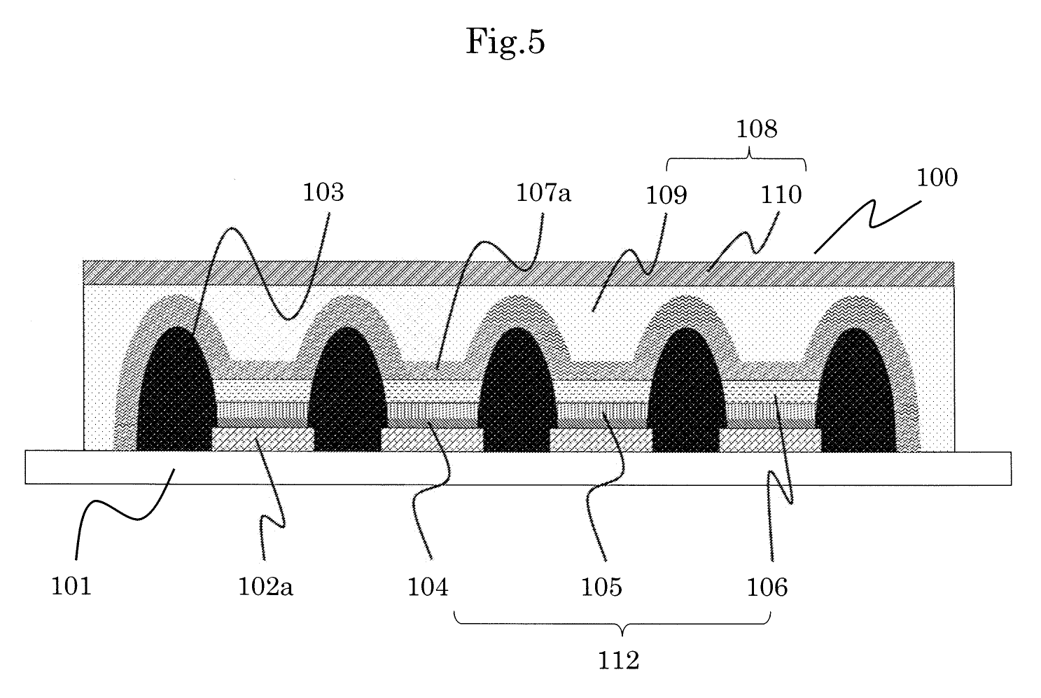

Furthermore, sealing can also be performed as follows. First, as shown in FIG. 5, the first electrode 102, the partition wall 103, the luminescent medium layer 112 and the second electrode 107 are formed on the substrate 101. Then, a resin layer 110 is formed on a sealing substrate 109. Next, sealing can be performed by adhering the sealing substrate and the substrate by the resin layer 110.

At this time, a material for the sealing material 109 is required to be a substrate material which has a low transmissivity of moisture and oxygen. In addition, as examples of the material, ceramics such as alumina, silicon nitride and boron nitride, glass such as no-alkali glass and alkali glass, quartz, and humidity resistance film can be exemplified. As examples of a humidity resistance film, a film which is made by forming SiOx on both sides of a plastic base material by CVD, a polymeric film to which a film having a low transmissivity and a film having water absorbability or a water absorbent are applied can be exemplified. In addition, moisture vapor transmission rate of the humidity resistance film is preferably equal to or less than 10⁻⁶ g/m²/day.

As examples of a material of the resin layer 110, the following material can be used. A photo-hardening adhesive property resin, a heat hardening adhesive property resin and two fluid hardening adhesive property resins including an epoxy type resin, acrylic resin, silicone resin or the like, acrylic resin such as ethylene ethylacrylate (EEA) polymer, vinyl resins such as ethylene vinyl acetate (EVA), thermoplastic resin such as polyamide, synthetic rubber, and thermoplastic adhesive property resins such as acid denatured substances of polyethylen or polypropylene. As examples of a method of forming the resin layer 110 on the sealing material, a solvent solution method, extrusion laminate method, fusion/hot melt method, calender method, discharge jet application method, screen printing method, vacuum laminate method and heated roll laminate method can be exemplified. A material having hygroscopicity or a property to absorb oxygen can be included in a resin layer if necessary. A thickness of the resin layer 110 formed on a sealing material 109 is selected arbitrarily depending on the size and the shape of an organic EL element which is sealed from the outside. However, the thickness is preferably about 5 μm˜500 μm.

Adhesion of the sealing body 108 to the substrate 101 on which the first electrode 102, the partition wall 103, the luminescent medium layer 112 and the second electrode 107 are formed is performed in a sealing room. When the sealing body has a two-layer structure having a sealing material and the resin layer 110 of thermoplastic resin, pressure bonding only is preferably performed by a heated roller When a heat hardening adhesive property resin is used, after pressure bonding is performed by a heated roller, heat hardening is preferably additionally performed at a hardening temperature. When a photo-hardening adhesive property resin is used, after pressure bonding is performed by a heated roller, hardening can be carried out by additional irradiation with radiation. Furthermore, here the resin layer 110 is formed on the sealing material 109. However, the sealing material 109 can be adhered to the resin layer 110 after the resin layer is formed on the substrate.

For example, as a passivation film, the sealing body 108 on which an inorganic thin film is formed can be formed before sealing is performed using the sealing material 109 or instead of using the sealing material. Moreover, these can be combined. As the passivation film, for example, silicon nitride, aluminum oxide, silicon oxide, calcium fluoride or the like can be used. However, a material is not limited to these in the present invention. A film of a material having an insulating property and a stability of moisture and oxygen can be formed by a vacuum film-formation method such as a vapor deposition method, an electron beam deposition method, a reactive deposition method, an ion plating method or a sputtering method.

A display element having this kind of structure has a structure in which the hole transport layer reflects luminescence light emitted from the luminescent layer. Therefore, it is possible to extract light which disappears in an organic thin film as guided wave light. Furthermore, luminescence light which is absorbed by the partition wall can be extracted by covering at least one part of the partition wall by the hole transport layer.

In addition, it is possible to form a thin film with a thickness equal to or less than 100 nm having a high reflectance ratio in addition to a conductive property and an energy level which are required as a hole transport material of an organic EL element. That is because as a material for the hole transport layer, oxide, sulfide or nitride of an inorganic compound which includes at least one kind of transition metal is used as a single layer, a stacked layer or a mixed layer.

In an organic electroluminescence display unit having the above mentioned structure, luminescence light can be extracted efficiently by reflecting luminescence light which disappears as guided wave light and display light which is absorbed by a partition wall off the hole transport layer.

### Example 1

An active matrix substrate 101 having an ITO thin film which was formed on chrome as a first electrode (a pixel electrode) 102 formed on a substrate 101 was used. The size of the substrate was 5 inches diagonally and the number of pixels was 320×240.

The partition wall 103 was formed so as to cover the edge part of the first electrode 102 formed on the substrate 101 and section the pixels. The film of the partition wall 103 was formed by a spin coating method so as to have a thickness of 2 μm on the entire surface of the substrate 101 using positive resist “ZWD6216-6” produced by ZEON corporation. Thereafter, the partition wall 103 was patterned to have a width of 40 μm using a photolithographic method. Therefore, a pixel area having the number of the subpixels of 960×240 dots and pitch of 0.12 mm×0.36 mm was sectioned.

The film of molybdenum oxide and indium oxide having a thicknesses of 50 nm was deposited together by a vacuum deposition method and patterned by a shadow mask as the hole transport layer 104 formed on the first electrode 102. The rate of the above deposition was controlled using a thickness monitor which was arranged on each deposition source. The blend ratio of molybdenum oxide and indium oxide was 1:4. The hole transport layer formed in this way had an average reflectance ratio of 65% in a visible area. The film of the hole transport layer was formed using a metal mask which has an apertural area of 120 m×100 mm such that a patterned area is formed on the entire surface of a display area.

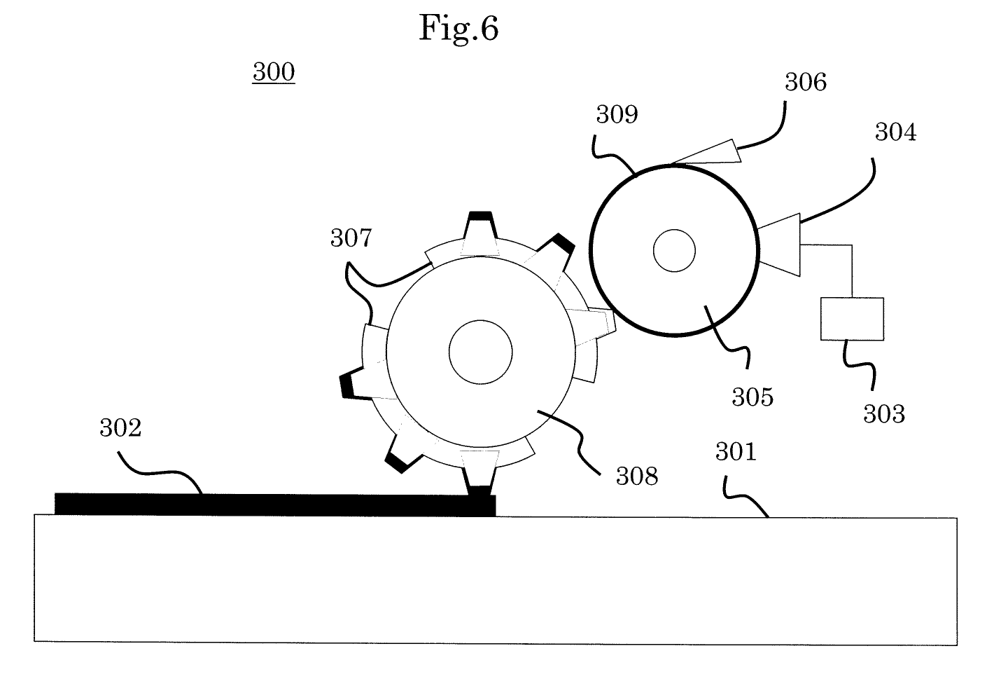

Thereafter, after the pixel electrode 102, the partition wall 103 and the hole transport layer 104 which were formed on the substrate 101 were set on the relief printing apparatus 300 as the substrate to be printed 302 as shown in FIG. 6, the interlayer 105 was printed right above the hole transport layer 104 formed on the pixel electrode 102 between the partition walls 103 so as to correspond to the line pattern of the hole transport layer 104 by a relief printing method using an ink where polyvinyl carbazole derivative which was a material for the interlayer 105 was dissolved in toluene to make the concentration of polyvinyl carbazole derivative 0.5%. In this case, an anilox roll 305 of 300 lines/inch and a relief printing plate 307 of photosensitive resin were used. The film thickness of the interlayer 105 after printing and drying was 10 nm.

After the pixel electrode 102, the partition wall 103, the hole transport layer 104 and the interlayer 105 which were formed on the substrate 101 were set on the relief printing apparatus 300 as the substrate to be printed 302, the luminescent medium layer 112 was printed right above the interlayer 105 sandwiched between the partition walls 103 so as to correspond to the line pattern of the interlayer 105 by a relief printing method using an ink where polyphenylene vinylene derivative which was a material for the luminescent medium layer 112 was dissolved in toluene to make the concentration of polyphenylene vinylene derivative 1%. In this case, an anilox roll 305 of 150 lines/inch and a relief printing plate 307 of photosensitive resin were used. The film thickness of the luminescent medium layer 112 after printing and drying was 80 nm.

Thereafter, the film of calcium was formed to have a thickness of 5 nm as the counter electrode 107 by a vapor deposition method using a metal mask having an apertural area of 120 mm×100 mm. After that, the film of aluminum was formed to have a thickness of 5 nm so as to be transparent using a metal mask which had an apertural area of 124 mm×104 mm.

Thereafter, the film of silicon nitride was formed to have a thickness of 300 nm as the sealing body 108 by CVD method and sealing was performed. Then, an organic electroluminescence display unit 100 obtained in this way was driven. Then, display properties having brightness of 150 cd/m² with 5V and luminescence efficiency of 12 cd/A with 20 mA/cm² were provided without brightness irregularity. Thus, uniform luminescence was obtained.

### Example 2

The process shown in Example 1 which was carried out until the hole transport layer 104 was formed was used for a process of manufacturing an organic EL display unit. In example 2, as the hole transport layer 104, a film of vanadium oxide (V₂O₅) and a film of zinc oxide (ZnO) with a thickness of 50 nm were deposited together by a vacuum deposition method and patterned using a shadow mask. At this time, the blend ratio of vanadium oxide and zinc oxide was 1:7. Thereafter, the interlayer 105, the luminescent medium layer 112, the counter electrode 107 and the sealing material 108 were manufactured by the same process shown in example 1.

The organic electroluminescence display unit 100 obtained in this way was driven. Then, display properties having brightness of 100 cd/m² with 5V and luminescence efficiency of 10 cd/A with 20 mA/cm² was provided without brightness irregularity. Thus, uniform luminescence was obtained.

### Comparative Example 1

The process shown in example 1 which was carried out until the hole transport layer 104 was formed was performed. In comparative example 1, as the hole transport layer 104, a film of PEDOT/PSS (polyethylen dihydroxy thiophen/polystyrene sulfonic acid) was formed to have a thickness of 50 nm by a spin coating method. Thereafter, the interlayer 105, the luminescent medium layer 112, the counter electrode 107 and the sealing material 108 were manufactured by the same process shown in example 1.

The organic electroluminescence display unit 100 obtained in this way was driven. Then, display properties having brightness of 100 cd/m² with 6V and luminescence efficiency of 9 cd/A with 20 mA/cm² were provided without brightness irregularity. In addition, uniform luminescence was obtained.

It became possible to extract light which disappears in an organic thin film as guided wave light because the hole transport layer having an inorganic compound has a function as a reflective layer. Furthermore, it became possible to extract display light which was being absorbed by the partition wall by covering at least one part of the partition wall by the hole transport layer. Therefore, an organic electroluminescence display unit of a top emission type with a high efficiency was obtained.

Thereafter, an acceleration test was performed for the organic electroluminescence display units obtained by examples 1 and 2 and comparative example 1 at a constant temperature and high humidity environment with a temperature of 60° C. and moisture content of 95%. As the result of this, after 1400 hours, a dark spot was found on the surface of the organic electroluminescence display unit obtained by comparative example 1. However, a dark spot was not found in the organic electroluminescence display units obtained by examples 1 and 2 even after 2000 hours. Therefore, the organic electroluminescence display unit 100 without defect in the display and with high light extraction efficiency was obtained.

What is claimed is:

1. An organic electroluminescence element comprising:
a hole transport layer having an inorganic compound and an organic luminescent layer which are between a first electrode and a second electrode which are arranged on a substrate, and wherein said organic luminescent layer is able to emit light which is reflected off said hole transport layer.

2. The organic electroluminescence element according to claim 1, wherein said inorganic compound includes one or more transition metals.

3. The organic electroluminescence element according to claim 1, wherein said inorganic compound includes a metal oxide material which has oxygen loss and metal brilliance.

4. The organic electroluminescence element according to claim 1, wherein an average reflectance ratio of said hole transport layer for light emitted from said organic luminescent layer is equal to or more than 50%.

5. The organic electroluminescence element according to claim 1, wherein a thickness of said hole transport layer is 10 nm-100 nm.

6. The organic electroluminescence element according to claim 1 further comprising a partition wall which sections at least said organic luminescent layer into a plurality of pixels.

7. The organic electroluminescence element according to claim 1, wherein said second electrode is a transparent electrode, and wherein said hole transport layer and said organic luminescent layer are stacked between said first electrode and said second electrode in this order from said first electrode.

8. The organic electroluminescence element according to claim 1, wherein said first electrode is a transparent electrode and wherein said organic luminescent layer and said hole transport layer are stacked between said first electrode and said second electrode in this order from said first electrode.

9. The organic electroluminescence element according to claim 3, wherein a work function of said metal oxide material is 4.0-6.5 eV.

10. The organic electroluminescence element according to claim 3, wherein said metal oxide material is any one of TiO₂, ZnO, NiO, Ta₂O₅, MoO₂, Ag₂O, CoO, Cr₂O₃, RuO₂ and In₂O₃.

11. The organic electroluminescence element according to claim 3 wherein said inorganic compound includes a hole transport material and said metal oxide material which has oxygen loss and metal brilliance, and wherein said hole transport material includes any one of Cu₂O, Cr₂O₃, Mn₂O₃, NiO, CoO, Pr₂O₃, Ag₂O, MoO₂, ZnO, TiO₂, V₂O₅, Nb₂O₅, Ta₂O₅, MoO₃, WO₃ and MnO₂.

12. The organic electroluminescence element according to claim 6, wherein said hole transport layer covers at least one part of said partition wall.

13. An image display unit comprising the organic electroluminescence element according to claim 1 as a display element.

14. An illuminating device comprising the organic electroluminescence element according to claim 1 as a luminescence element.

15. A method for manufacturing an organic electroluminescence element including a hole transport layer which has an inorganic compound and an organic luminescent layer which are between a first electrode and a second electrode which are arranged on a substrate, said method comprising:
forming said first electrode on said substrate;
forming said hole transport layer which reflects light emitted from said organic luminescent layer to said first electrode;
forming said organic luminescent layer on said hole transport layer; and
forming said second electrode on said organic luminescent layer.

16. The method for manufacturing an organic electroluminescence element according to claim 15, wherein said hole transport layer is formed by mixing a plurality of inorganic compounds by a dry film formation method.

17. The method for manufacturing an organic electroluminescence element according to claim 15, wherein said organic luminescent layer is formed by a wet film formation method using an ink including an organic luminous material.

18. The method for manufacturing an organic electroluminescence element according to claim 15 further comprising forming a partition wall which sections a plurality of pixels on a substrate, wherein said hole transport layer is formed on an entire surface of a display area which includes said partition wall and said first electrode.

19. The method for manufacturing an organic electroluminescence element according to claim 16, wherein said hole transport layer is formed by mixing said plurality of inorganic compounds by depositing together.

20. The method for manufacturing an organic electroluminescence element according to claim 19, wherein said inorganic compounds include a metal oxide material and wherein oxygen loss occurs in at least one of said metal oxide materials at the time of a deposition or after a film-formation.
